(19) United States
(12) Patent Application Publication
(10) Pub. No.: US 2023/0298859 A1
(43) Pub. Date: Sep. 21, 2023

(54) OPTIMIZING EDGE RADICAL FLUX IN A DOWNSTREAM PLASMA CHAMBER

(71) Applicant: LAM RESEARCH CORPORATION, Fremont, CA (US)

(72) Inventors: Andrew Stratton BRAVO, Piedmont, CA (US); Pilyeon PARK, San Jose, CA (US); Serge KOSCHE, San Francisco, CA (US); Julien Augustin MONBEIG, Hillsboro, OR (US); Mark KAWAGUCHI, San Carlos, CA (US); Stephen WHITTEN, Danville, CA (US); Shih-Chung KON, Fremont, CA (US)

(21) Appl. No.: 18/010,423

(22) PCT Filed: Dec. 14, 2021
(86) PCT No.: PCT/US2021/072903

§ 371 Date: Dec. 14, 2022

Related U.S. Application Data
(60) Provisional application No. 63/126,644, filed on Dec. 17, 2020.

(51) Int. Cl. H01J 37/32; H05B 1/02

(52) U.S. Cl. CPC H01J 37/32422; H01J 37/32357; H01J 37/3244; H05B 1/0252; H01J 2237/334

(57) ABSTRACT

A showerhead for a processing chamber in a substrate processing system includes an upper portion having a lower surface and an upper surface and a faceplate. A lower surface of the faceplate is below the lower surface of the upper portion such that the showerhead extends into an interior volume of the processing chamber and the faceplate includes a plurality of holes arranged in a pattern to provide fluid communication between a remote plasma source above the showerhead and the interior volume of the processing chamber. A sidewall extends upward from an outer edge of the faceplate between the faceplate and the upper portion and the upper portion extends radially outward from the sidewall of the showerhead and is configured to be mounted on a sidewall of the processing chamber. A heater is embedded in the upper portion of the showerhead.

### CROSS-REFERENCE TO RELATED APPLICATIONS

This application claims the benefit of U.S. Provisional Application No. 63/126,644, filed on Dec. 17, 2020. The entire disclosure of the application referenced above is incorporated herein by reference.

### FIELD

The present disclosure relates improved processing of substrates in remote plasma source substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform treatments on substrates such as semiconductor wafers. Examples of the treatments include deposition, etching, cleaning, etc. The substrate processing systems typically include a processing chamber including a substrate support, a gas delivery system and a plasma generator.

During processing, the substrate is arranged on the substrate support. Different gas mixtures may be introduced by the gas delivery system into the processing chamber. In some applications, radio frequency (RF) plasma such as inductively coupled plasma (ICP) may be used to activate chemical reactions.

ICP produces both highly reactive neutral species and ions to modify wafer surfaces. As customer devices become increasingly complicated and sensitive, controlling exposure of the substrate to the plasma is increasingly important. Ions generated within the plasma can have damaging effects on sensitive materials within device structures. The ions can modify the properties of device materials and adversely affect the performance of the overall structure.

### SUMMARY

A showerhead for a processing chamber in a substrate processing system includes an upper portion having a lower surface and an upper surface and a faceplate. A lower surface of the faceplate is below the lower surface of the upper portion such that the showerhead extends into an interior volume of the processing chamber and the faceplate includes a plurality of holes arranged in a pattern to provide fluid communication between a remote plasma source above the showerhead and the interior volume of the processing chamber. A sidewall extends upward from an outer edge of the faceplate between the faceplate and the upper portion and the upper portion extends radially outward from the sidewall of the showerhead and is configured to be mounted on a sidewall of the processing chamber. A heater is embedded in the upper portion of the showerhead.

In other features, the heater extends from the upper portion into the sidewall of the showerhead. The heater is annular and tilts downward such that an inner diameter of the heater is lower than an outer diameter of the heater. The pattern includes the plurality of holes arranged in a plurality of concentric rings. The pattern includes regions that do not include any of the plurality of holes. The regions are concentric regions. The plurality of holes are blocked in selected regions of the plurality of concentric rings. The concentric rings are non-uniformly spaced in a radial direction.

In other features, a system includes the showerhead and the sidewall of the showerhead and the sidewall of the processing chamber define an annular pocket around the showerhead. The system further includes a controller configured to control a temperature of the showerhead using the heater.

A processing chamber for a substrate processing system includes a lower surface, an upper surface, and a sidewall defining an interior volume, a substrate support arranged in the interior volume of the processing chamber, and a showerhead arranged above the substrate support. The showerhead includes an upper portion and a faceplate. The showerhead extends into the interior volume of the processing chamber such that a lower surface of the faceplate is below the upper surface of the processing chamber. A sidewall extends upward from an outer edge of the faceplate between the faceplate and the upper portion, the upper portion extends radially outward from the sidewall of the showerhead and is configured to be mounted on the sidewall of the processing chamber, and an annular pocket is defined around the showerhead between the sidewall of the showerhead and the sidewall of the processing chamber.

In other features, the processing chamber further includes a heater embedded in the upper portion of the showerhead. The heater extends from the upper portion into the sidewall of the showerhead. The heater is annular and tilts downward such that an inner diameter of the heater is lower than an outer diameter of the heater. The processing chamber further includes a remote plasma source arranged above the showerhead and the faceplate includes a plurality of holes arranged in a pattern to provide fluid communication between the remote plasma source and the interior volume of the processing chamber. The pattern includes the plurality of holes arranged in a plurality of concentric rings. The pattern includes regions that do not include any of the plurality of holes. The regions are concentric regions. The plurality of holes are blocked in selected regions of the plurality of concentric rings. The concentric rings are non-uniformly spaced in a radial direction.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIG. 2A is a processing chamber including an example showerhead according to the present disclosure;

FIGS. 2B and 2C show example configurations of a heater embedded within the showerhead according to the present disclosure;

FIG. 2D is a side view of an example showerhead according to the present disclosure;

FIG. 2E is a top view of an example showerhead according to the present disclosure;

FIG. 2F is a bottom view of an example showerhead according to the present disclosure;

FIG. 2G is a top isometric view of an example showerhead according to the present disclosure;

FIG. 2H is a bottom isometric view of an example showerhead according to the present disclosure;

FIGS. 3A, 3B, and 3C are plan views of example faceplates of a showerhead according to the present disclosure; and

FIG. 4 illustrates steps of an example method of performing an etch process using a showerhead according to the present disclosure.

In the drawings, reference numbers may be reused to identify similar and/or identical elements.

### DETAILED DESCRIPTION

Some substrate processing systems are configured to generate plasma remotely (i.e., in a location external to a processing chamber). Remote plasma substrate processing systems include a gas distribution device such as a showerhead or showerhead assembly arranged between an upper region of a processing chamber where plasma is generated and a lower region of the processing chamber where a substrate is located. The showerhead may be configured to function as a filter (e.g., an ion filter) for blocking or filtering ions and/or ultraviolet (UV) light. For example, the showerhead may comprise a faceplate or grid including a plurality of holes arranged in a pattern.

The showerhead may be configured to filter ions generated by the plasma and/or control plasma uniformity. Processes (e.g., etching processes) are sensitive to plasma uniformity. For example, plasma non-uniformity may cause different amounts of material to be removed from a substrate, resulting in variation in etching uniformity within a single substrate and from substrate to substrate. Accordingly, the showerhead controls plasma flow, ion filtering, and radical flux to maintain etching uniformity. Process parameters and processing chamber conditions (such as temperature) may further affect plasma and etching uniformity.

A showerhead according to the principles of the present disclosure includes various features configured to tune and maintain desired plasma and etch uniformity (e.g., an etch profile). For example, the showerhead includes an embedded heater, and a controller is configured to control the heater to control a temperature of the showerhead. A lower (bottom) portion of the showerhead may protrude/extend into an interior volume of the processing chamber. A gap between a lower surface of the showerhead (e.g., a lower surface of the faceplate or grid) and the substrate can be optimized for specific processing chambers and/or applications. An arrangement of the holes (e.g., hole diameter, pitch, pattern, etc.) in the faceplate may also be optimized. For example, holes may be omitted/blocked in specific regions of the faceplate to tune the etch profile.

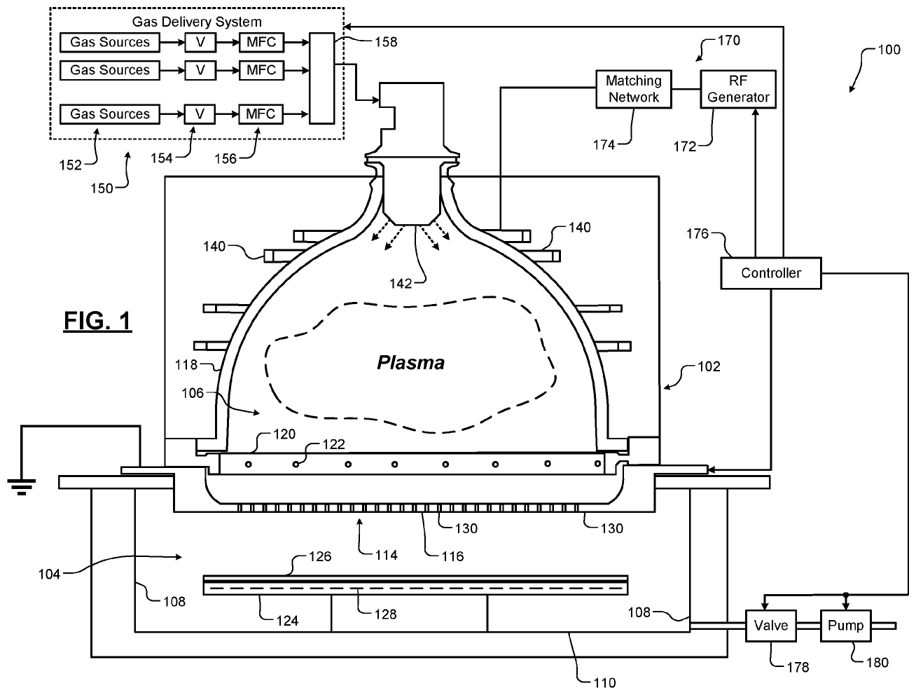

Referring now to FIG. 1, a substrate processing system 100 includes a processing chamber (i.e., a substrate processing chamber) 102. Although the processing chamber 102 is shown as an inductively coupled plasma (ICP) based system, the examples disclosed herein may be applied to other types of substrate processing systems such as transformer coupled plasma (TCP) or downstream plasma systems.

The processing chamber 102 includes a lower chamber region 104 and an upper chamber region 106. The lower chamber region 104 is defined by chamber sidewall surfaces 108, a chamber bottom surface 110, and a lower surface of a gas or plasma distribution device such as a showerhead assembly including a showerhead 114. For example, the showerhead 114 may include a faceplate or grid 116 configured to function as an ion and/or UV filter/blocker. In some examples, the faceplate 116 is connected to a reference potential such as ground (as shown in FIG. 1). In other examples, the faceplate 116 may be connected to a positive or negative DC reference potential.

The upper chamber region 106 is defined by an upper surface of the showerhead 114 and an inner surface of a dome 118. In some examples, the dome 118 rests on a first annular support 120 including one or more spaced holes 122 for delivering process gas to the upper chamber region 106. In some examples, the process gas is delivered by the one or more spaced holes 122 in an upward direction at an acute angle relative to a plane including the showerhead 114, although other angles/directions may be used. A gas flow channel in the first annular support 120 may be used to supply gas to the one or more spaced holes 122.

The substrate support 124 is arranged in the lower chamber region 104. In some examples, the substrate support 124 includes an electrostatic chuck (ESC), although other types of substrate supports can be used. A substrate 126 is arranged on an upper surface of the substrate support 124 during processing such as etching. In some examples, a temperature of the substrate 126 may be controlled by heating elements (or a heater plate) 128, an optional cooling plate with fluid channels and one or more sensors (not shown), and/or any other suitable substrate support temperature control systems.

One or more inductive coils 140 may be arranged around an outer portion of the dome 118. When energized, the one or more inductive coils 140 create an electromagnetic field inside of the dome 118. In some examples, an upper coil and a lower coil are used. A gas injector 142 injects one or more gas mixtures from a gas delivery system 150. The gas delivery system 150 includes one or more gas sources 152, one or more valves 154, one or more mass flow controllers (MFCs) 156, and a mixing manifold 158, although other types of gas delivery systems may be used.

In some examples, the gas injector 142 includes a center injection location that directs gas in a downward direction and one or more side injection locations that inject gas at one or more angles with respect to the downward direction. In some examples, the gas delivery system 150 delivers a first portion of the gas mixture at a first flow rate to the center injection location and a second portion of the gas mixture at a second flow rate to the side injection locations of the gas injector 142. In other examples, different gas mixtures are delivered by the gas injector 142. In some examples, the gas delivery system 150 delivers tuning gas to other locations in the processing chamber.

A plasma generator 170 may be used to generate RF power that is output to the one or more inductive coils 140. Plasma is generated in the upper chamber region 106. In some examples, the plasma generator 170 includes an RF generator 172 and a matching network 174. The matching network 174 matches an impedance of the RF generator 172 to the impedance of the one or more inductive coils 140. Although a single RF source (i.e., RF generator 172) is shown, in other examples multiple RF sources may be used to supply two or more different pulsing levels. A valve 178 and a pump 180 may be used to control pressure inside of the lower and upper chamber regions 104, 106 and to evacuate reactants.

A controller 176 communicates with the gas delivery system 150, the valve 178, the pump 180, and/or the plasma generator 170 to control flow of process gas, purge gas, RF plasma and chamber pressure. In some examples, plasma is sustained inside the dome 118 by the one or more inductive coils 140. One or more gas mixtures are introduced from a top portion of the processing chamber 102 using the gas injector 142 (and/or holes 122).

The showerhead 114 according to the present disclosure includes one or more features configured to tune a desired etch profile of etching performed on the substrate 126. For example, the showerhead 114 may include an embedded heater (not shown in FIG. 1). The controller 176 is configured to control the heater to control a temperature of the showerhead 114 and maintain the desired etch profile. The faceplate 116 includes holes 182 arranged to flow plasma from the upper chamber region 106, through the faceplate 116, and into the lower chamber region. An arrangement of the holes 182 (e.g., hole diameter, pitch, pattern, etc.) according to the present disclosure may be optimized to achieve a desired etch profile. For example, the holes 182 may be omitted/blocked in specific regions of the faceplate 116. The showerhead 114 according to the present disclosure may also protrude/extend into the lower chamber region 104 (i.e., into an interior volume of the processing chamber 102).

In this manner, the temperature of the showerhead 114, the arrangement of the holes 182, and/or a gap between a lower surface of the faceplate 116 and the substrate 126 may be optimized to achieve the desired etch profile as described below in more detail.

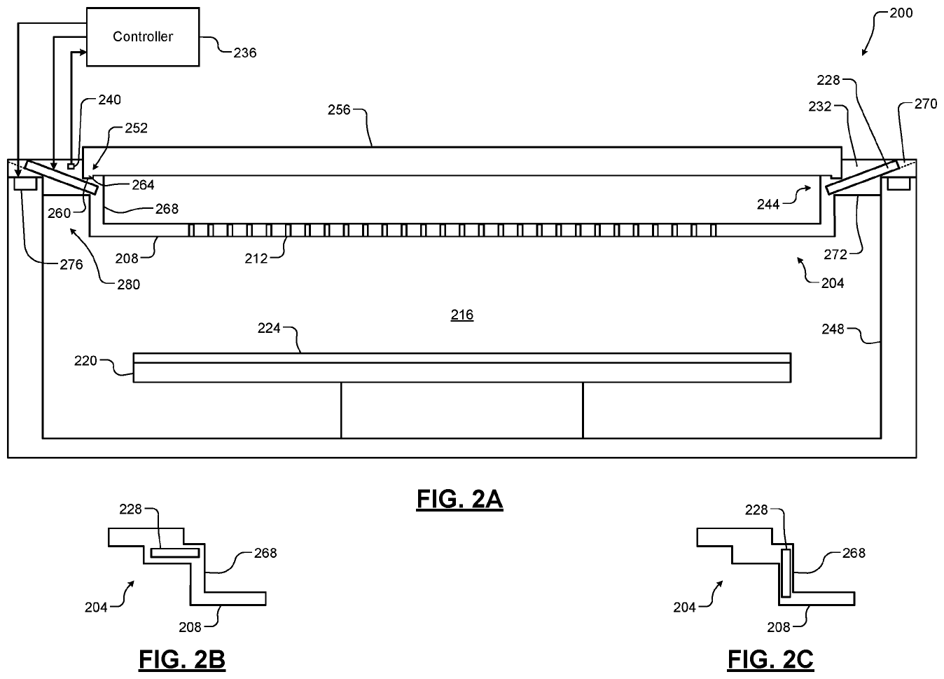

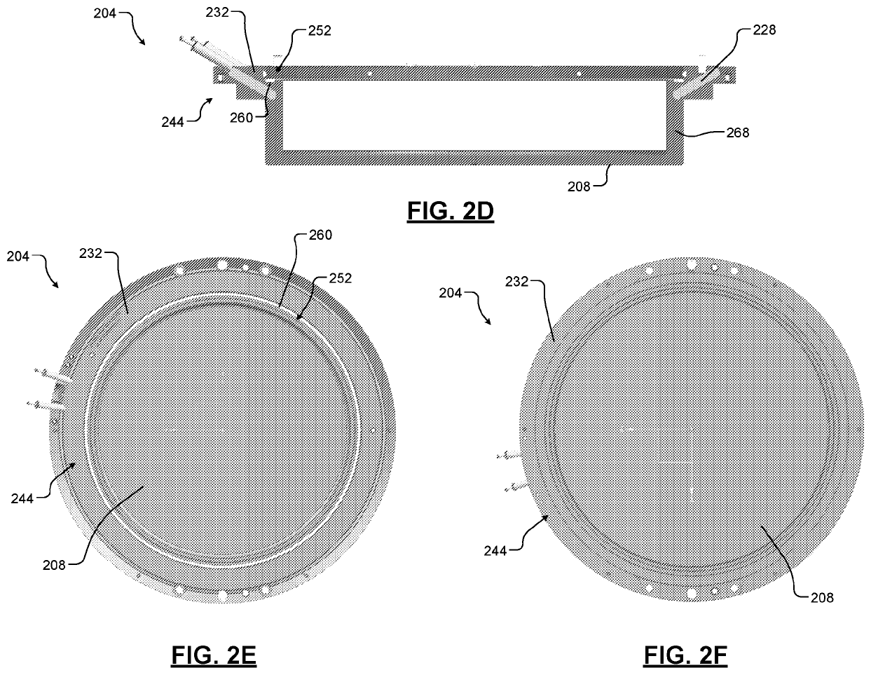

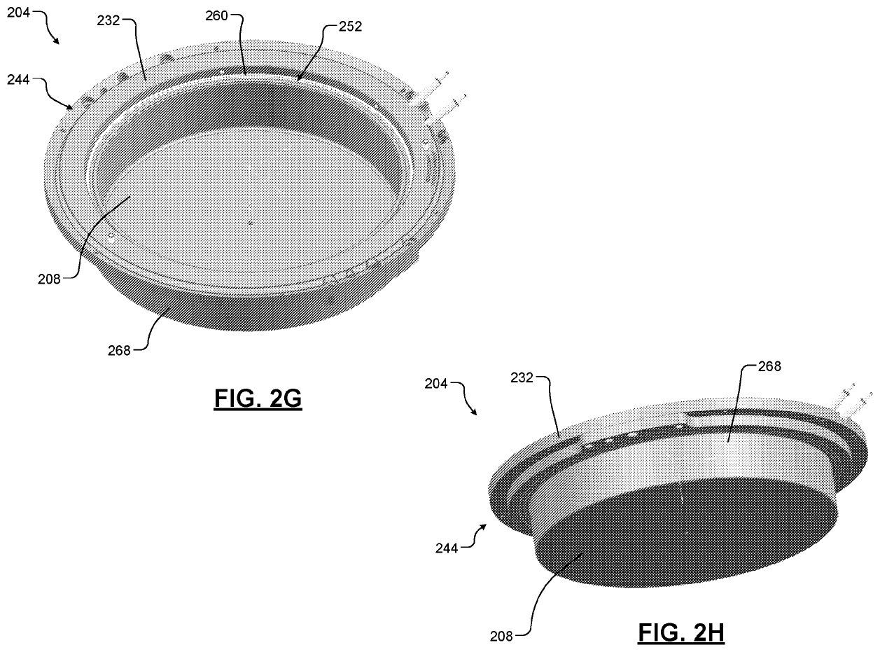

Referring now to FIGS. 2A, 2B, 2C, 2D, 2E, 2F, 2G, and 2H, a processing chamber 200 includes an example showerhead 204 according to the present disclosure. FIG. 2D is a side view of the showerhead 204. FIG. 2E is a top view of the showerhead 204. FIG. 2F is a bottom view of the showerhead 204. FIG. 2G is a top isometric view of the showerhead 204. FIG. 2H is a bottom isometric view of the showerhead 204.

The showerhead 204 includes a faceplate or grid 208 including a plurality of holes 212 arranged to flow plasma through the faceplate 208 and into an interior volume 216 of the processing chamber 200 as described above in FIG. 1. A substrate support (e.g., a pedestal) 220 is arranged to support a substrate 224 during processing (e.g., etching). An arrangement of the holes 212 may be optimized to achieve a desired etch profile as described below in more detail. The faceplate 208 may be coated in a material such as yttria. For example, the yttria coating may be applied in using a conformal atomic layer deposition (ALD) process. In this manner, the yttria coating is applied to interior surfaces of the holes 212.

A heater (e.g., a resistive heater or heating element) 228 is embedded within a body 232 of the showerhead 204 according to some embodiments. A controller 236 (e.g., corresponding to the controller 176 of FIG. 1) is configured to control the heater 228 to control a temperature of the showerhead 204 and maintain the desired etch profile. For example, the controller 236 may control the heater 228 to maintain the showerhead 204 at a desired constant temperature. During processing, various factors may cause the temperature of the showerhead 204 to change (i.e., increase and decrease). The factors may include, but are not limited to, temperature within the processing chamber 200, plasma flow, RF power provided to generate the plasma, a duration of processing, a combination thereof, etc. The controller 236 is configured to control the heater 228 to maintain the temperature of the showerhead 204 (e.g., at a setpoint temperature) to compensate for temperature changes during processing.

For example, the setpoint temperature may be a calibrated or fixed temperature (e.g., stored in memory of the controller 236) for a particular application or process, a setpoint input by a user, a dynamic temperature (e.g., a temperature that is adjusted during processing based on other processing parameters), etc. The controller 236 may adjust the heater 228 (i.e., increase or decrease power provided to the heater 228) based on a temperature of the showerhead (a showerhead temperature) 204. The showerhead temperature may be sensed or measured, estimated, modeled or calculated, etc. For example, the showerhead 204 may include an embedded sensor 240 arranged to sense the showerhead temperature and provide the showerhead temperature to the controller 236. In other embodiments, the controller 236 may estimate or calculate the showerhead temperature based on process parameters (e.g. plasma source temperature, a sensed or estimated temperature of the substrate support, power, process duration, etc.).

In an embodiment, the heater 228 may be a zoned heater including a plurality of separately controllable zones. The zones may correspond to different azimuthal regions of the showerhead 204. The heater 228 may be separately controlled based on the desired etch profile, which may include different control parameters in different ones of the zones. For example, the heater 228 may be controlled to compensate for and/or introduce azimuthal non-uniformities. The controller 236 may separately control the zones based on signals received from respective sensors arranged to sense the temperatures in the different zones.

As shown, the heater 228 is arranged in an upper portion 244 of the showerhead 204. For example, a lower surface of the upper portion 244 may be stepped as shown to facilitate mounting on a sidewall or sidewalls 248 of the processing chamber 200. Conversely, an upper surface of the upper portion 244 may include a step 252 configured to support an annular support 256 (e.g., corresponding to the annular support 120), a lower portion of the dome 118, etc. The step 252 may include a groove 260 configured to interface with a downward-facing rim 264 on a lower surface of the annular support 256. The groove 260 and rim 264 facilitate alignment and retention of the annular support 256 on the showerhead 204.

The heater 228 may be generally annular. As shown, the heater 228 is sloped (i.e., tilted) inward and downward. In other words, an inner diameter of the heater 228 is lower (in a vertical direction) than an outer diameter of the heater 228. The sloped configuration of the heater 228 facilitates positioning of the heater 228 within the upper portion 244. In particular, the sloped configuration allows the heater 228 to extend through the stepped configuration of the upper portion 244 and into a vertical sidewall 268 of the showerhead 204. For example, the sidewall 268 extends upward from an outer edge or perimeter of the faceplate 208 between the faceplate 208 and the upper portion 244. The upper portion 244 extends generally radially outward from the sidewall 268 toward the sidewall 248 of the processing chamber 200.

In this manner, the heater 228 is located as near as possible to the faceplate 208 to facilitate heat transfer from the heater 228 and into the faceplate 208 through the sidewall 268. In other embodiments, the heater 228 may have a horizontal configuration (as shown in FIG. 2B), may be embedded in the sidewall 268 in a vertical configuration such that the heater 228 extends into the faceplate 208 (as shown in FIG. 2C), etc. In still other embodiments, the heater 228 may be embedded in the faceplate 208 in a horizontal configuration. In an embodiment, the heater 228 may have a stepped or “L”-shaped profile. For example, the heater 228 may include a vertical portion arranged in the sidewall 268 and a horizontal portion extending from the vertical portion into at least one of the upper portion 244 and the faceplate 208.

In some embodiments, the showerhead 204 is manufactured with the heater 228 integrated within the upper portion 244. In other embodiments, the showerhead 204 may be manufactured to include a tilted slot 270 or other opening (e.g., a horizontal, vertical, or “L”-shaped slot or pocket) configured to receive the heater 228 subsequent to manufacture. For example, the slot 270 may be machined into the upper portion 244 and the heater 228 is installed in the slot 270 subsequent to manufacture.

The showerhead 204 extends into the interior volume 216 of the processing chamber 200. In other words, the faceplate 208 and the holes 212 of the showerhead 204 are below (e.g., not coplanar with and offset in a vertical direction from) a lower surface of the upper portion 244 and an upper surface 272 of the processing chamber 200. In other words, a lower surface of the faceplate 208 facing the interior volume 216 is below the upper surface 272 of the processing chamber 200. As shown, the upper surface 272 of the processing chamber 200 is defined by the lower surface of the upper portion 244. In other embodiments, the processing chamber 200 may include an upper wall or ceiling that extends radially inward from the sidewall 248 and the upper portion 244 is supported on the upper wall. In these embodiments, a lower surface of the upper wall defines the upper surface 272 of the processing chamber 200.

A depth of the showerhead 204 (i.e., an amount that the showerhead 204 extends into the interior volume 216) defines a gap between a lower surface of the faceplate 208 and the substrate 224. The gap (i.e., a gap width or distance) is optimized to achieve a desired etch profile. For example, etch uniformity may vary across different processes, processing chambers, etc. Accordingly, the showerhead 204 is configured to achieve a desired gap for a particular process and/or processing chamber. For example, the gap may be varied between 1 and 3 inches (e.g., 25 to 76 mm). In one embodiment, the showerhead 204 may be removed and replaced to adjust the gap. In another embodiment, the faceplate 208 and the vertical portion 268 may be separable from the upper portion 244 and selectively removed and replaced to adjust the gap. For example, a length of the vertical portion 268 may be varied by replacing the vertical portion 268 or an assembly including the vertical portion 268 and the faceplate 208.

Although described with respect to the gap, the principles of the present disclosure also apply (conversely) to a protrusion depth of the showerhead 204. The protrusion depth may be defined as a distance between the upper surface 272 of the processing chamber 200 and the faceplate 208 (e.g., an upper surface of lower surface of the faceplate 208). Accordingly, as the protrusion depth increases, the gap decreases. Conversely, as the protrusion depth decreases, the gap increases.

In one embodiment, the showerhead 204 may be configured to be raised and lowered to adjust the gap. For example, one or more actuators (e.g., a bellows actuator, a linear actuator, etc.) 276 may be arranged between the sidewall 248 and the upper portion 244 of the showerhead 204. The controller 236 is configured to raise and lower the showerhead 204 using the actuators 276 to adjust the gap. In still other embodiments, the substrate support 220 may be raised and lowered to adjust the gap.

The showerhead 204 according to the present disclosure defines a pocket (e.g., an annular pocket) 280 between the showerhead 204 and the sidewall 248. The pocket surrounds the showerhead 204. For example, radicals energized within the interior volume 216 bounce/reflect off of surfaces of the sidewall 248 and the upper surface 272 of the processing chamber 200. The reflected radicals are directed toward an outer edge of the substrate 224 and cause etch non-uniformities (e.g., an increased or decreased etch rate at the outer edge of the substrate 224 relative to an interior of the substrate, edge roll-up or roll-down, etc.).

The showerhead 204 according to the present disclosure blocks the reflected radicals from reaching the substrate 224. In other words, since the showerhead 204 extends downward into the interior volume 216, the pocket 280 is formed and the reflected radicals are retained within the pocket 280. A pocket depth (which may correspond to the protrusion depth of the showerhead 204) and a width of the pocket 280 determines an amount of the reflected radicals that are blocked/prevented from reaching the substrate 224. Accordingly, the pocket depth may be optimized for particular processes and/or processing chambers. For example, permitted some reflected radicals to reach the substrate 224 may be desirable. In this manner, the protrusion depth (and, correspondingly, the gap and the pocket depth) may be optimized to obtain a desired etch profile.

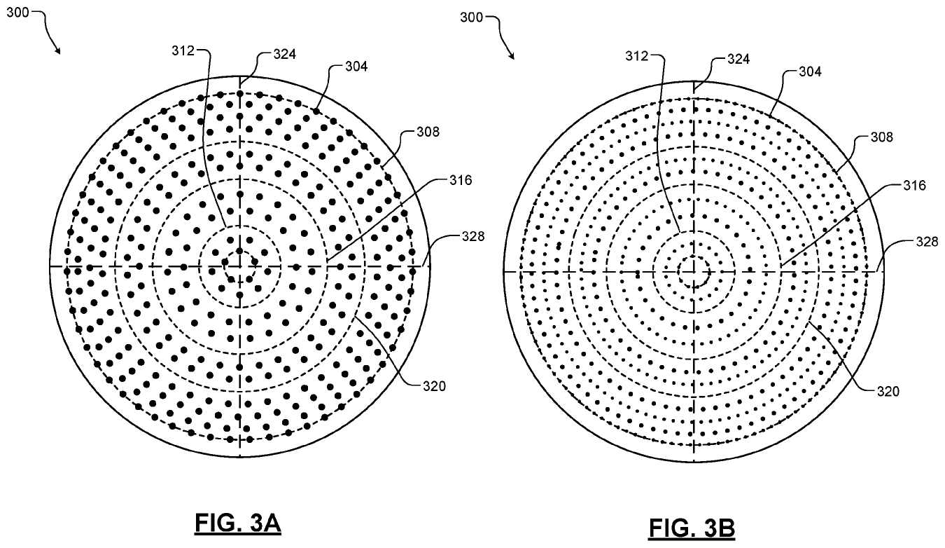

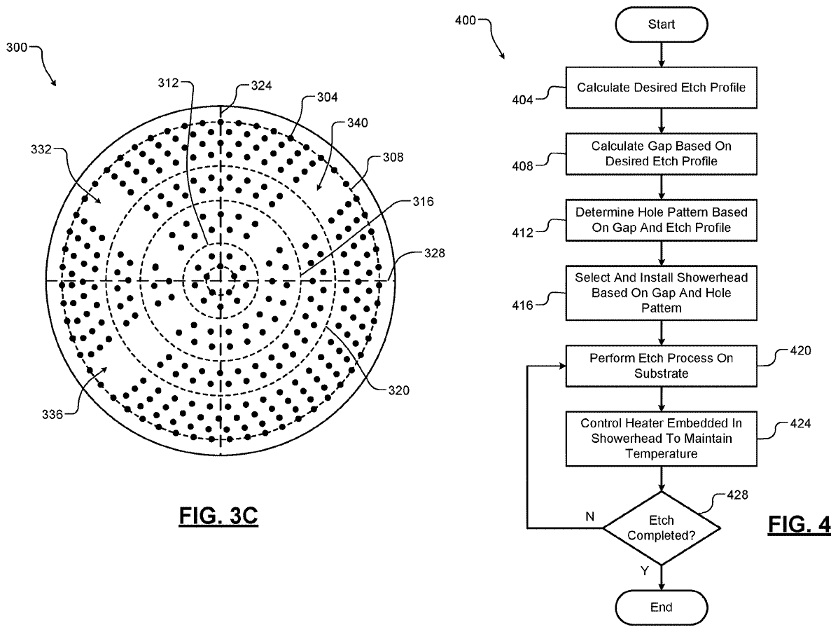

Referring now to FIGS. 3A, 3B, and 3C, top or bottom views of various examples of a faceplate 300 according to the present disclosure are shown. The faceplate 300 includes a plurality of holes 304 arranged to achieve a desired etch profile. For example, the holes 304 are arranged according to an optimized hole diameter, pitch, and/or pattern. In some embodiments, specific regions of the holes 304 in the faceplate 300 are omitted/blocked to tune the etch profile.

As shown, the holes 304 are arranged in a plurality of rings (e.g., concentric rings) 308. Dashed lines in FIGS. 3A, 3B, and 3C illustrate the alignment of the holes 304 in rings. The holes 304 in respective ones of the rings 308 may be uniformly spaced in an azimuthal direction. In other examples, the holes 304 in selected ones of the rings 308 may be non-uniformly spaced. Selected regions of the faceplate 300 do not include any of the holes 304, and/or the holes 304 are blocked in the selected regions of the faceplate 300. For example, dashed lines 312, 316, and 320 show respective regions (e.g., concentric ring rings) of the faceplate 300 that do not include the holes 304. In other words, a concentric ring of the holes 304 is omitted in each of the regions 312, 316, and 320. In an embodiment, the rings 308 are generally uniformly spaced apart in a radial direction. Accordingly, omitting rings in the regions 312, 316, and 320 causes non-uniform spacing between the rings 308 adjacent to the regions 312, 316, and 320.

The regions 312, 316, and 320 may correspond to regions of the substrate 224 where increased or decreased etch rates are desired. For example, the increased or decreased etch rates reduce etch non-uniformities across the substrate 224. In some embodiments, the increased or decreased etch rates may intentionally introduce etch non-uniformities.

Although, as shown in FIG. 3A, three of the rings of holes 304 (corresponding to the regions 312, 316, and 320) are omitted, fewer or more of the rings may be omitted in other embodiments. For example, as shown in FIG. 3B, more than three of the rings of holes 304 are omitted. Quantity and locations of the omitted rings may be varied to optimize the hole pattern and achieve a desired etch profile for a specific process and/or processing chamber.

As shown in FIG. 3A, the holes 304 of the rings 308 may be aligned in a radial direction along one or more axes. For example, the holes 304 of alternating ones of the rings 308 are aligned in a first radial direction (e.g., along an upper Y-axis 324) but not along an X-axis 328. While the holes 304 may be uniformly spaced in a given one of the rings 308, a spacing (i.e., pitch) of the holes 304 may vary in respective rings 308. Similarly, diameters of the holes 304 may be the same or may vary in respective rings 308. For example, as shown in FIG. 3B, diameters of the holes 304 in respective rings 308 are different. In other embodiments, the holes 304 may be omitted and/or blocked in regions other than the concentric regions described in FIGS. 3A and 3B. For example, as shown in FIG. 3C, the holes 304 are further omitted in azimuthal regions 332, 336, and 340.

Referring now to FIG. 4, an example method 400 of performing an etch process using a showerhead according to the present disclosure is shown. At 404, a desired etch profile for a selected process, processing chamber, substrate type, etc. is calculated. For example, the etch profile may be calculated based on desired etch rates and etch uniformity across a surface of the substrate.

At 408, a gap or gap width is calculated based on the desired etch profile. For example, the gap may be a calibrated gap in accordance with a given process and/or processing chamber. In some embodiments, the gap is determined using stored data, such as a lookup table that correlates a desired etch profile with a respective gap. Additionally or alternatively, a protrusion depth and/or pocket depth is determined at 408. For example, a protrusion depth and/or the gap may be determined based on a desired pocket depth. In some embodiments, the gap may be adjusted automatically using a controller and actuator as described above in FIG. 2A.

At 412, a desired hole pattern is determined based on the desired etch profile and the determined gap. For example, a plurality of hole patterns may be correlated to respective gaps and etch profiles. Each hole pattern may include one or more regions (e.g., ring regions) of a faceplate where holes are omitted based on the desired etch profile as described above in FIGS. 3A, 3B, and 3C.

At 416, a showerhead and/or faceplate is selected and installed based on the calculated gap and determined hole pattern. At 420, an etch process is performed on a substrate in a processing chamber that includes the selected showerhead. At 424, a heater embedded in the showerhead is controlled during the etch process to maintain a desired showerhead temperature. At 428, the method 400 determines whether the etch process is complete. If true, the method 400 ends. If false, the method 400 continues the etch process at 420.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a processing chamber in a substrate processing system, the showerhead comprising:
an upper portion having a lower surface and an upper surface;
a faceplate, wherein a lower surface of the faceplate is below the lower surface of the upper portion such that the showerhead extends into an interior volume of the processing chamber, and wherein the faceplate includes a plurality of holes arranged in a pattern to provide fluid communication between a remote plasma source above the showerhead and the interior volume of the processing chamber;
a sidewall extending upward from an outer edge of the faceplate between the faceplate and the upper portion, wherein the upper portion extends radially outward from the sidewall of the showerhead and is configured to be mounted on a sidewall of the processing chamber; and
a heater embedded in the upper portion of the showerhead.

2. The showerhead of claim 1, wherein the heater extends from the upper portion into the sidewall of the showerhead.

3. The showerhead of claim 1, wherein the heater is annular, and wherein the heater tilts downward such that an inner diameter of the heater is lower than an outer diameter of the heater.

4. The showerhead of claim 1, wherein the pattern includes the plurality of holes arranged in a plurality of concentric rings.

5. The showerhead of claim 4, wherein the pattern includes regions that do not include any of the plurality of holes.

6. The showerhead of claim 5, wherein the regions are concentric regions.

7. The showerhead of claim 4, wherein the plurality of holes are blocked in selected regions of the plurality of concentric rings.

8. The showerhead of claim 4, wherein the concentric rings are non-uniformly spaced in a radial direction.

9. A system comprising the showerhead of claim 1, wherein the sidewall of the showerhead and the sidewall of the processing chamber define an annular pocket around the showerhead.

10. A system comprising the showerhead of claim 1 and further comprising a controller configured to control a temperature of the showerhead using the heater.

11. A processing chamber for a substrate processing system, the processing chamber comprising:
a lower surface, an upper surface, and a sidewall defining an interior volume;
a substrate support arranged in the interior volume of the processing chamber; and
a showerhead arranged above the substrate support, the showerhead comprising
an upper portion,
a faceplate, wherein the showerhead extends into the interior volume of the processing chamber such that a lower surface of the faceplate is below the upper surface of the processing chamber, and
a sidewall extending upward from an outer edge of the faceplate between the faceplate and the upper portion, wherein the upper portion extends radially outward from the sidewall of the showerhead and is configured to be mounted on the sidewall of the processing chamber, and wherein an annular pocket is defined around the showerhead between the sidewall of the showerhead and the sidewall of the processing chamber.

12. The processing chamber of claim 11, further comprising a heater embedded in the upper portion of the showerhead.

13. The processing chamber of claim 12, wherein the heater extends from the upper portion into the sidewall of the showerhead.

14. The processing chamber of claim 12, wherein the heater is annular, and wherein the heater tilts downward such that an inner diameter of the heater is lower than an outer diameter of the heater.

15. The processing chamber of claim 11, further comprising a remote plasma source arranged above the showerhead, wherein the faceplate includes a plurality of holes arranged in a pattern to provide fluid communication between the remote plasma source and the interior volume of the processing chamber.

16. The processing chamber of claim 15, wherein the pattern includes the plurality of holes arranged in a plurality of concentric rings.

17. The processing chamber of claim 16, wherein the pattern includes regions that do not include any of the plurality of holes.

18. The processing chamber of claim 17, wherein the regions are concentric regions.

19. The processing chamber of claim 16, wherein the plurality of holes are blocked in selected regions of the plurality of concentric rings.

20. The processing chamber of claim 16, wherein the concentric rings are non-uniformly spaced in a radial direction.
